(19) United States
(12) Patent Application Publication
(10) Pub. No.: US 2006/0043546 A1
(43) Pub. Date: Mar. 2, 2006

(54) Optoelectronic component and housing

(76) Inventor: Robert Kraus, Regensburg (DE)

Correspondence Address: FISH & RICHARDSON PC, P.O. BOX 1022, MINNEAPOLIS, MN, 55440-1022, US

(21) Appl. No.: 11/202,646

(22) Filed: Aug. 12, 2005

(30) Foreign Application Priority Data
Aug. 31, 2004 (DE) 10 2004 042 186.2

(51) Int. Cl. H01L 23/495

(52) U.S. Cl. 257/676

(57) ABSTRACT

Disclosed is a housing for an optoelectronic component comprising a reflector and a heat dissipating element, wherein the housing comprises a mounting portion with at least one mounting area for mounting a semiconductor chip or a component provided with at least one semiconductor chip, plus at least one reflector wall implemented as a heat dissipating element, which is connected thermally conductively to the mounting area and through which the heat is dissipated from the housing. Also disclosed is an optoelectronic component provided with such a housing.

### CROSS REFERENCE TO RELATED APPLICATION

This Application claims priority to German Application No. 10 2004 042 186.2, filed Aug. 31, 2004. The contents of the prior application is hereby incorporated by reference.

### BACKGROUND

The invention relates to a housing for an optoelectronic component and an optoelectronic component comprising such a housing.

A housing for an optoelectronic component is disclosed in WO 02/084749. It comprises a leadframe with two electrical connectors formed from a basic housing body made of plastic molding compound. The basic body has a recess that leads to a chip mounting area and whose side faces are inclined and serve as a reflector.

To dissipate heat, the housing has a thermal connector that includes the chip mounting area and through which the housing can be thermally connected to a mounting side. In a component provided with such a housing, a semiconductor chip is mounted on the chip mounting area and the recess of the housing is filled with a potting compound to form a closed housing. The potting compound is substantially composed of a thermally insulating material, such as a reactive resin, for example, and the basic housing body is also made of plastic, so that heat can be dissipated substantially only through the thermal connector.

U.S. Pat. No. 6,274,924 B1 also discloses a housing for an optoelectronic component with a recess implemented as a reflector, which housing has a thermal connector on a side facing away from the recess. In a component provided with a housing of this kind, a light-emitting semiconductor chip in the recess is electrically and thermally mounted in the housing and is encapsulated with a potting compound to form a closed housing. A lens is additionally constructed over the potting compound.

A common feature of the types of housings described is that the back of the housing has to be connected thermally to an external heat sink for heat to be dissipated effectively from the housing. Hence, components with housings of this kind have to have specially designed, thermally well-conducting mounting surfaces, which in many respects limits their field of application.

### SUMMARY

Preferred embodiments of the present invention provide a housing of the type described above in which adequate heat dissipation is ensured regardless of how the component is mounted. An optoelectronic component provided with such a housing is further proposed.

According to one aspect of the invention, a housing has at least one mounting area for mounting a semiconductor chip or a component comprising at least one semiconductor chip. The reflector has at least one reflector wall that extends away from the mounting area in an intended radiation direction of the semiconductor chip and is connected thermally conductively to a mounting area. The reflector wall is implemented as a heat dissipating element to remove heat from the housing by thermal radiation and convection.

The housing comprises a reflector that is not fully encapsulated by or intended to be encapsulated with a thermally insulating material, but instead has at least one reflector portion that extends from a mounting portion of the housing outward and thus away from said mounting portion into the environment of the housing, or lies completely outside the mounting portion. The term “mounting portion” is to be understood in particular as that portion of a housing that is necessary for receiving, mounting, electrically connecting and closedly or openly housing a semiconductor chip. It can also include in particular a portion of the reflector, for example the floor of a reflector cup or a portion of the reflector walls. Portions of the reflector walls that, for example, extend outward past the intended boundary of a potting compound or other covering of the semiconductor chip thus are not part of the mounting portion, but instead are to be construed as belonging to the reflector portion.

At least the reflector wall or the reflector portion and particularly the reflector as a whole is fashioned as a heat dissipating element, so that heat due to energy losses can be dissipated not only through a mounting side for mounting the housing for example on a circuit board, but also, additionally or alternatively, through the reflector wall or the reflector portion immediately adjacent the environment of the component.

The reflector walls in this context are used in particular to dissipate the heat to the environment by radiation and convection. Additionally or alternatively, the reflector preferably comprises a thermal connector for thermally connecting the housing, or the reflector portion is connected thermally conductively to a thermal connector of the housing. Taken as a whole, this permits a form of heat dissipation that is both an alternative to and an improvement over the arrangements known from the prior art.

The reflector preferably comprises a reflector cup. A portion of the reflector cup advantageously includes the mounting area, such that a semiconductor chip or a component is, for example, mounted on the floor of the reflector cup. In a corresponding optoelectronic component provided with the housing, the semiconductor chip is preferably encased in the mounting portion to protect it against external influences. This is advantageously accomplished by means of either a potting compound or a cover plate, said cover plate advantageously additionally being configured as an optical element.

The reflector wall usefully comprises a metal and, alternatively or additionally, a thermally well-conducting ceramic material.

The reflector wall preferably comprises a material from the group consisting of aluminum, copper, silver, platinum, palladium, gold, chromium, aluminum nitride and aluminum oxide.

In a particularly preferred embodiment, the reflector wall or a heat-conducting wall segment has a thickness of 0.5 mm or more. Such a thickness for the wall segment or the wall makes it possible to achieve sufficiently high thermal conductivity inside the reflector or for the reflector.

The reflector wall is preferably constructed at least partially as double-walled, i.e., the reflector wall comprises at least a first wall with reflecting subareas, with a subsidiary, second wall disposed on the side facing away from the reflecting subareas. The gap between the two walls of a double wall is preferably as free as possible from solid or liquid matter. The surface area of the reflector through which heat can be dissipated to the environment can be significantly increased in this way, thereby improving heat removal from the housing.

Particularly preferably, at least one of the two walls of the double-walled portion of the reflector is provided with at least one vent hole, so that warm air can escape from the gap in the double wall and be replaced accordingly with cooler air.

In a further preferred embodiment of the housing, subareas of the reflector wall are additionally or alternatively provided with cooling ribs. The surface area through which heat can be dissipated can also be significantly increased by the use of cooling ribs.

The housing advantageously comprises an electrical circuit for converting an electrical voltage. The housing can in this way be implemented to operate on standardized voltages of the kind that are present for example in the case of conventional connectors for lamps, such as incandescent lamps or discharge lamps, for example. The electrical circuit preferably comprises, additionally or alternatively, an arrangement for generating a fixedly defined electrical current.

Particularly advantageously, the housing comprises at least one base provided with a thread or at least one base provided with contact pins, by means of which the housing can be externally electrically connected to and mounted in a holder for conventional lamps, such as incandescent lamps or discharge lamps, for example.

The optoelectronic component comprises according to the invention a housing in accordance with one of the previously described embodiments. In addition, the component comprises at least one semiconductor chip that is connected thermally conductively to the reflector portion.

The semiconductor chip is advantageously mounted on the mounting area. Alternatively, a component comprising at least one semiconductor chip in a chip housing and a thermal connector is advantageously mounted on the mounting area.

Additional aspects, embodiments, and advantages of the invention will emerge from the exemplary embodiments described below.

### BRIEF DESCRIPTION OF DRAWINGS

FIG. 1 is a schematic sectional view of a first exemplary embodiment of the housing and the component,

FIG. 2 is a schematic sectional view of a second exemplary embodiment of the housing and the component,

FIG. 3 is a schematic sectional view of a third exemplary embodiment of the housing and the component,

FIG. 4 is a schematic sectional view of a fourth exemplary embodiment of the housing and the component,

FIG. 5 is a schematic sectional view of a fifth exemplary embodiment of the housing and the component,

FIG. 6 is a schematic plan view of an exemplary embodiment of a mounting area of the housing and the component with semiconductor chips mounted thereon, and

FIG. 7 is a schematic sectional view of a sixth exemplary embodiment of the housing and the component.

In the exemplary embodiments and figures, like or like-acting parts are provided with the same reference numerals. The illustrated elements in the figures are not to be considered true to scale, but may in part be depicted as over-large to furnish a better understanding.

### DETAILED DESCRIPTION

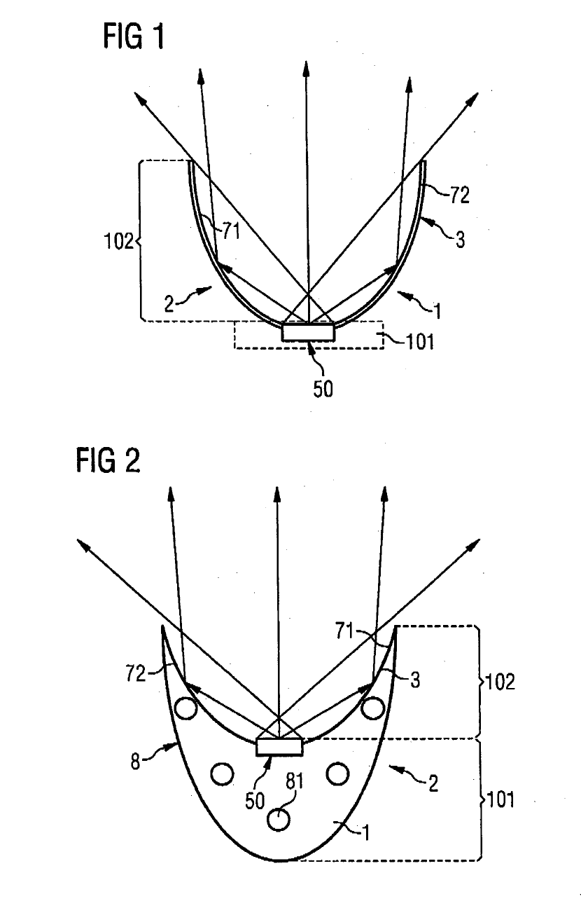

The optoelectronic component 2 illustrated in FIG. 1 comprises a light source 50 and a reflector 3, said reflector having for example a rotationally symmetrical reflector cup. Light source 50 is mounted in or on reflector 3 and includes at least one semiconductor chip (not shown). This semiconductor chip is connected thermally conductively to reflector 3, reflector 3 being implemented as a heat dissipating element. To this end, the reflector has for example reflector walls 72 made of a thermally conductive material, such as, for example, a metal or a thermally well-conducting ceramic material.

The reflector walls 72 are made for example of aluminum, aluminum nitride or aluminum oxide, or they substantially comprise, for example, copper coated on the surfaces inside the reflector cup with a reflective metal, for example silver, platinum, palladium, gold or chromium, that is, the reflector cup has reflective inner walls 71.

Optoelectronic component 2 comprises a housing 1, in or on which are disposed at least one semiconductor chip, electrical contact material or wiring for the semiconductor chip, and, optionally, encapsulating, sealing or covering material. Housing 1 includes a mounting portion 101 that includes the light source 50 and a portion of the reflector 3. Mounting portion 101 is therefore the portion in which the at least one semiconductor chip is arranged and optionally encased to protect it against external influences. From mounting portion 101, a reflector portion 102 extends in a radiation direction of mounting portion 101 (see the electromagnetic rays indicated by arrows) and away therefrom. The reflector portion is, for example, completely free of thermally insulating material, and heat can therefore be radiated through all the outer surfaces of the reflector wall 72 in the region of reflector portion 102.

Heat generated by the at least one semiconductor chip 5 during the operation thereof is conducted by mounting portion 101 into reflector portion 102, permitting good heat dissipation into the surrounding air through outer surfaces of the reflector or at least of the reflector portion.

With respect to the component 2 depicted in FIG. 2, in contrast to the exemplary embodiments described above in connection with FIG. 1, reflector 3 is constructed not with just one reflector wall 72 but as double-walled, i.e., with a double wall 8. The second wall of reflector 3, i.e., the wall that does not define the reflector cup comprising reflective inner surface 71, extends at a distance from first reflector wall 71 that becomes greater the closer it is to mounting portion 101. In mounting portion 101, this wall extends such that it forms a relatively large volume, which is filled for example with a gas, for example air, to which heat is transferred by the inner surfaces of double wall 8.

The radiation output of the reflector cup is, for example, roughly 50 mm in diameter.

In order for heated air to escape from the double-walled chamber and cooler air to get in, the double wall 8 comprises a plurality of vent holes 81, although an arbitrarily shaped single opening in the double wall 8 is also feasible instead of a plurality of individual holes. The entire double wall 8 is made, for example, of a thermally well-conducting material, e.g. of aluminum, so that the heat is distributed over the entire double wall and can be dissipated from a total outer surface area of the walls of the reflector 3 that is more than twice that of the component depicted in FIG. 1. With this type of housing, cooling can take place at least primarily by thermal radiation and convection. In addition, the double wall has a greater thermal capacity than a single reflector wall 72 with a wall thickness of comparable size.

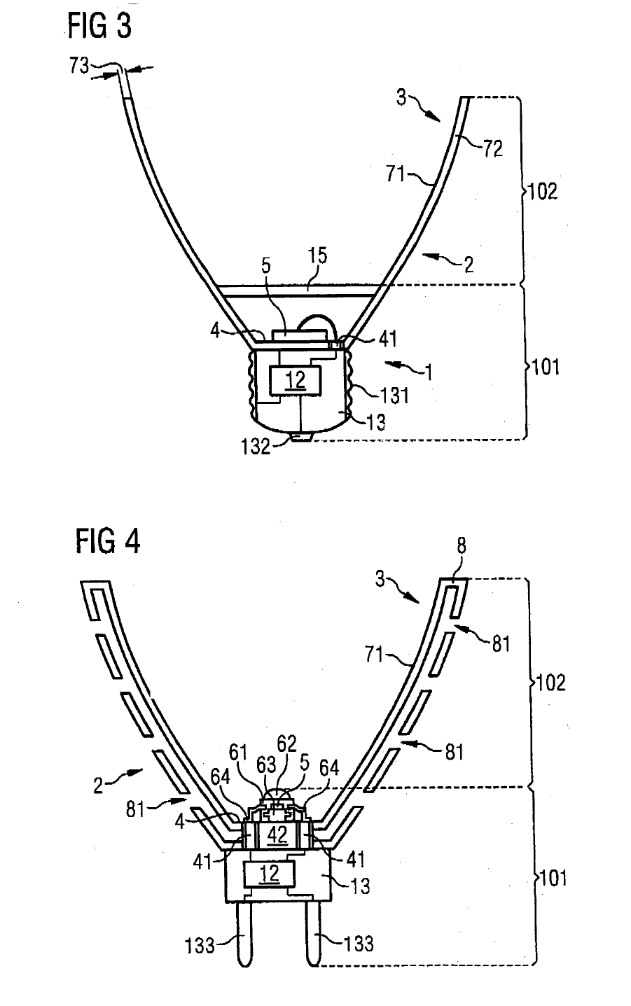

FIG. 3 provides an illustration of a further exemplary embodiment of component 2 and housing 1 that is somewhat more detailed than FIGS. 1 and 2. The reflector 3 is constructed as single-walled with a thermally conductive reflector wall 72, the reflector wall in this case defining a reflector cup with reflective inner surfaces 71 whose floor forms a mounting area 4 on which an electromagnetic radiation emitting semiconductor chip 5 is mounted.

Mounting area 4 comprises a through-connection 41, to which the semiconductor chip 5 is connected electrically conductively by means of a bonding wire on a side facing away from mounting area 4, and which is electrically isolated from the reflector floor.

The reflector 3 is made, for example, of an electrically conductive material, for example of a metal, and the side of semiconductor chip 5 facing mounting area 4 is, for example, electrically conductively connected by solder to the floor of the reflector cup, so that the reflector 3 also functions as an electrical contact for the semiconductor chip 5.

Housing 1 comprises a base 13, which is adjacent reflector 3 on a side of reflector wall 72 opposite mounting area 4. Integrated into the base is an electrical circuit 12 that is connected electrically between the electrical contacts 72, 41 and external electrical contacts 131, 132 of base 13. A first external electrical contact 131 of base 13 has a thread, and a second external electrical contact 132 of base 13 is centrally disposed on a side of the base facing away from reflector 3, such that component 2 with the base can be electrically connected and mounted in a holder for conventional lamps. The holder is, for example, an E27 or E28 holder.

The electrical circuit 12 is so constituted for example that a voltage that is customarily applied to holders for conventional lamps, for example 230 V or 12 V, is transformed into a voltage suitable for driving semiconductor chip 5 or for generating a fixedly defined current suitable for driving semiconductor chip 5.

Disposed inside the reflector cup of reflector 3 is a cover plate 15 by which the semiconductor chip 5 is protected against external influences, such as, for example, mechanical influences or moisture. Cover plate 15 comprises a radiation-transparent material, for example glass, and is disposed as close as possible to semiconductor chip 5, so that a large proportion of the reflective inner walls 71 lie outside the region enclosed by cover plate 15. In this way, the heat generated by the semiconductor chip 5 when it is operating can be emitted unhindered through a large proportion of the inner walls 71 without being dammed up in the region sealed off by cover plate 15.

In the housing 1 illustrated in FIG. 3, mounting portion 101 extends to the level on reflector 3 at which cover plate 15 is to be disposed. The reflector walls 72 project from mounting portion 101 in a radiation direction away therefrom and form reflector portion 102.

The cover plate need not necessarily be implemented as a plate, but can also be implemented as an optical element, e.g. as lens-shaped or lens-like. The outer surface of cover plate 15 can additionally or alternatively be roughened, thereby reducing total reflection from the cover plate 15 and, in particular, multiple total reflection inside the space sealed off by cover plate 15.

The reflector wall 72 has for example a thickness 73 of 1.5 or 2 mm, whereby both good thermal conductivity and good stability can be imparted to the reflector.

The component 2 depicted in FIG. 4 comprises a further example of a double-walled reflector 3. Here again, the double wall 8 defines a reflector cup with reflective inner surfaces 71. The wall of double wall 8 that is disposed on the side of the reflector facing away from the reflector cup extends, for example, parallel to the inner wall defining the reflector cup and comprises vent holes 81.

Similarly to the component depicted in FIG. 3, a mounting area 4 is formed by the floor of the reflector 3 or reflector cup, the reflector 3 comprising in this area two electrical through-connections 41 and a thermal connection 42 that thermally interconnects the two walls of double wall 8. Because of thermal connection 42, the heat can be conducted away from mounting area 4 directly into both walls of the double wall 8 and does not have to first pass along the entire inner wall of the reflector 3 to reach the outer wall of double wall 8. This further improves heat dissipation. The reflector 3 in this case serves not only as a heat dissipating element, but also as a heat sink, since the double-walled construction of the reflector 3 increases not only the external area, but also the thermal capacity of the reflector 3.

Mounted on mounting area 4 is a semiconductor chip 5 in the form of a component comprising a chip housing 61. Chip housing 61 comprises electrical connectors 64, each of which is connected electrically conductively to the electrical through-connections 41, for example by means of solder or an electrically conductive adhesive. In addition, chip housing 61 comprises a thermal base 63 on which semiconductor chip 5 rests and to which it is thermally bonded.

On its opposite side from semiconductor chip 5, thermal base 63 rests on the thermal through-connection 42 of mounting area 4 and is also thermally conductively connected thereto, so semiconductor chip 5 is thermally connected to reflector 3. Semiconductor chip 5 is encapsulated in the chip housing by means of a radiation-transparent potting compound, on which a lens 62 is disposed. With the component 2 illustrated in FIG. 4, therefore, no further measures are needed to protect the semiconductor chip 5 against external influences.

In the component illustrated in FIG. 4, the external electrical contacts of base 13 are implemented as electrical contact pins 133, so that the component can be electrically connected and mounted by means of a plug for conventional lamps.

The optoelectronic component 2 depicted in FIG. 5 comprises further modifications over the components described hereinabove with reference to FIGS. 3 and 4. Thus, the reflector wall 72 of reflector 3 is provided externally, i.e. on a side facing away from reflective inner face 71, with cooling ribs 10, thereby increasing the heat-radiating area of reflector 3 as well as the thermal capacity thereof. The cooling ribs 10 can be implemented either as an alternative to a double-walled reflector 3, as shown in FIG. 5, or as a complement thereto (not shown).

A semiconductor chip 5 is disposed on mounting area 4, directly on chip carrier 51 connected thermally conductively to reflector 3. The chip carrier is made of an electrically insulating and thermally well conducting material, for example of aluminum nitride, and is coated with an electrically conductive layer 53 by which the semiconductor chip 5 is connected electrically conductively to a first connection side. A second connection side of semiconductor chip 5 is connected electrically conductively by means of a bonding wire to a first electrical through-connection 41 of mounting area 4, while the electrically conductive coating 53 of chip carrier 51 and thus the first connection side of semiconductor chip 5 is connected electrically conductively by means of a bonding wire 52 to a second electrical through-connection 41. The semiconductor chip 5 is encapsulated by means of a potting compound 14, said potting compound being, for example, a radiation-transparent resin, e.g. an epoxy resin, or a silicone-based compound.

The mounting portion of housing 1 extends from an external electrical contact 132 of base 13, which can be constructed analogously to the base of the component depicted in FIG. 3, to the fill level of potting compound 14. From there, reflector portion 102 extends in a radiation direction of mounting portion 101 and away therefrom. Heat can dissipated from the housing 2 by radiation and convection for example through the entire reflector wall 72 and particularly through reflective portion 102 of reflector 103. Alternatively, reflector 3 or reflector wall 72 can also be made in part of a thermally insulating material and/or covered with a thermally insulating material. However, at least a large proportion of the reflector wall is preferably free of thermally insulating material.

For the sake of simplicity, only a single semiconductor chip 5 or a single semiconductor component 6 comprising a single semiconductor chip is shown in the exemplary embodiments of FIGS. 3 to 5. It is, of course, equally possible, and actually preferred in many applications, to use a plurality of semiconductor chips, a plurality of components or a component provided with a plurality of semiconductor chips. Exemplarily, the component comprises 8 to 10 semiconductor chips, each of which can, for example, be operated with electric power of 1 to 1.5 W. The component as a whole can, for example, be operated with electric power of 10 W or up to 15 W.

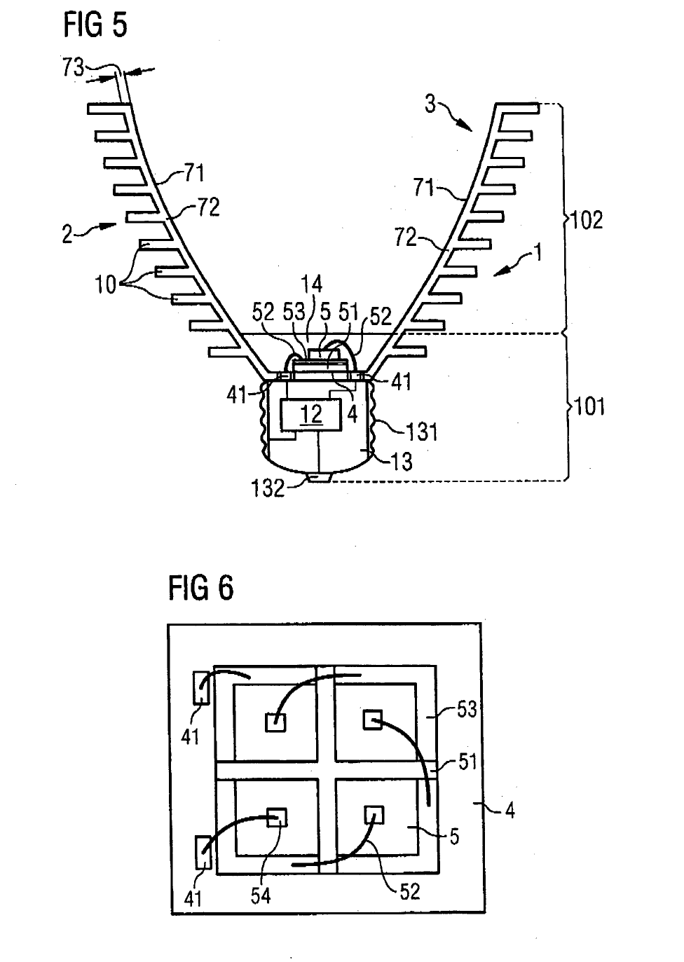

Depicted in FIG. 6 is an example comprising four semiconductor chips 5, which, like the semiconductor chip illustrated in FIG. 5, are disposed on a chip carrier 51. Chip carrier 51 is disposed on a mounting area 4 provided with two electrical through-connections 41 and, on a side facing away from the mounting area 4, with four mutually separated surfaces comprising an electrically conductive layer 53. A semiconductor chip 5 is disposed on each of these electrically conductive coatings 53, which coatings 53 have a larger surface area than the footprint of the semiconductor chip 5.

The semiconductor chips 5 are interconnected in series via the electrically conductive coatings 53 and the bonding pads 54 by means of bonding wires 52. This series circuit is connected electrically conductively to the electrical through-contacts 41. Instead of using bonding wires 52, it is also, of course, possible to electrically contact semiconductor chips and connect them together electrically in alternative ways. One possibility, for example, is the use of flip chips, in which both of the electrical contact surfaces of the semiconductor chip are on the same side and can therefore be connected directly to electrical connectors by soldering or adhesive bonding.

Although the mounting area in FIG. 6 has a square or quadrangular footprint, mounting area 4 can basically have any conceivable continuous footprint, particularly a circular footprint.

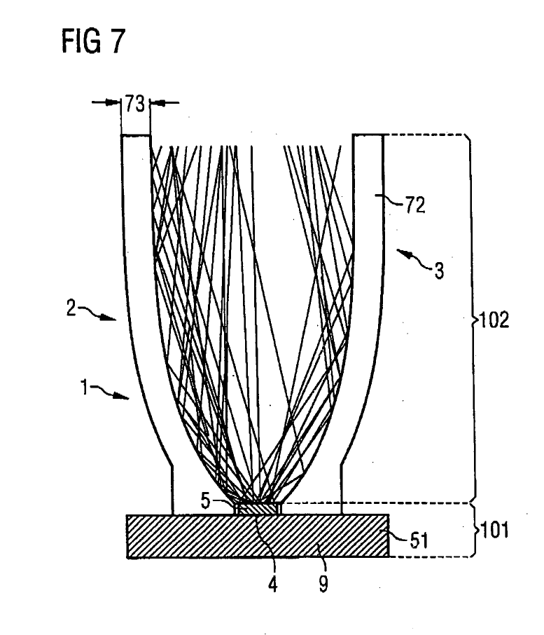

The optoelectronic component 2 illustrated in FIG. 7 has as its floor a chip carrier 51 that is, for example, implemented as a printed circuit board and has a thermally conductive basic body. A semiconductor chip 5 is mounted on chip carrier 51 and connected both thermally and electrically conductively thereto. Chip carrier 51 functions as a heat sink, and an opposite side of chip carrier 51 from semiconductor chip 5 can be used as an external thermal connection by means of which the component can be thermally connected externally.

Additionally disposed on chip carrier 51 is a reflector 3, which is made of a heat-conducting material and is connected thermally conductively to the chip carrier. Reflector 3 has a relatively small radiation input compared to the size of semiconductor chip 5. For example, a cavity defined by the reflector walls 72 on a side facing the chip mounting area and perpendicular to an optical axis of the reflector is no wider than 1.5 times the lateral edge length of the semiconductor chip 5. The reflector is additionally implemented as a compact parabolic concentrator (CPC), making it possible in particular to generate radiation cones of very low divergence and high radiation density.

The maximum aperture angle of a radiation cone generated by the component is, for example, 15°, for which purpose the reflector has a length along its optical axis that is roughly nine times the width of the radiation input. The maximum aperture angle of the emitted radiation cone is, for example, 30° or less, preferably 20° or less, particularly preferably 15° or less. In the case of an advantageous maximum aperture angle of about 9°, the length of the reflector along its optical axis is approximately 23 times the radiation input.

The protective scope of the invention is not limited by the description of the invention with reference to the exemplary embodiments. Thus it is not necessary, for example, for the reflector to be made entirely of thermally well conducting material as long as good heat dissipation from the reflector wall or the reflector portion is assured. In addition, the reflector can comprise a plurality of segments with different optical axes, that are connected by optical deflecting elements such as, for example, lenses, prisms or mirrors, by means of which the electromagnetic radiation is deflected from one segment into the next. The invention encompasses any novel feature and any combination of features, particularly including any combination of the features contained in the claims, even if that feature or that combination is itself not mentioned explicitly in the claims or the exemplary embodiments.

Accordingly, additional embodiments are within the scope of the following claims.

What is claimed is:

1. A housing for an optoelectronic component comprising:
at least one mounting area for mounting a semiconductor chip or a component comprising at least one semiconductor chip; and
a reflector comprising at least one reflector wall that projects away from the mounting area in an intended radiation direction of the semiconductor chip and is connected thermally conductively to the mounting area,
wherein the reflector wall is configured to function as a heat dissipating element for dissipating heat from the housing by radiation and convection.

2. The housing as recited in claim 1,
wherein the reflector wall comprises a metal and/or a thermally well conducting ceramic material.

3. The housing as recited in claim 1,
wherein the reflector wall comprises a material from the group consisting of aluminum, copper, silver, platinum, palladium, gold, chromium, aluminum nitride and aluminum oxide.

4. The housing as recited in claim 1,
wherein the reflector wall or at least a heat-conducting wall segment of the reflector wall has a thickness of 0.5 mm or more.

5. The housing as recited in claim 1,
wherein the reflector wall is constructed at least partially as double-walled.

6. The housing as recited in claim 5,
wherein one of the two walls of the double-walled portion of the reflector wall is provided with at least one vent hole.

7. The housing as recited in claim 1,
wherein the reflector comprises a thermal connection for thermally connecting the housing or is connected thermally conductively to a thermal connection of the housing.

8. The housing as recited in claim 1,
wherein the reflector wall is provided with cooling ribs.

9. The housing as recited in claim 1,
wherein the housing comprises an electrical circuit for converting an electrical voltage.

10. The housing as recited in claim 1,
wherein the housing comprises at least one base provided with a thread or at least one base provided with contact pins for externally electrically connecting and mounting the housing by means of a holder or a plug for conventional lamps.

11. An optoelectronic component comprising:
a housing as recited in claim 1; and
at least one semiconductor chip that is connected thermally conductively to the reflector wall.

12. The optoelectronic component as recited in claim 11,
wherein the semiconductor chip is mounted thermally conductively on the mounting area.

13. The optoelectronic component as recited in claim 11,
wherein a component provided with a semiconductor chip in a chip housing that has a thermal connection is mounted in the housing.
